(19) United States
(12) Patent Application Publication
(10) Pub. No.: US 2025/0147084 A1
(43) Pub. Date: May 8, 2025

(54) ENERGY SYSTEM WITH INCOMPLETE MEASUREMENT DATA

(71) Applicant: SIEMENS SCHWEIZ AG, ZÜRICH (CH)

(72) Inventors: Sebastian Thiem, Neustadt an der Aisch (DE); Stefan Niessen, Erlangen (DE)

(21) Appl. No.: 18/835,629

(22) PCT Filed: Feb. 10, 2023
(86) PCT No.: PCT/EP2023/053313

§ 371 Date: Aug. 2, 2024

(30) Foreign Application Priority Data
Feb. 16, 2022 (EP) 22156980.9

(51) Int. Cl. G01R 21/133

(52) U.S. Cl. CPC G01R 21/1333

(57) ABSTRACT

A method for evaluating measurement values of an energy system is provided, wherein the energy system includes components which are interconnected by energy flows. Measurement values are available for only a portion of the energy flows. Values are calculated for at least some energy flows for which no measurement values are available by successively considering different subsystems of the energy system, and in each subsystem a value is calculated for one or more energy flows.

### CROSS-REFERENCE TO RELATED APPLICATIONS

This application is a national stage of PCT Application No. PCT/EP2023/053313, having a filing date of Feb. 10, 2023, which claims priority to EP Application Serial No. 22156980.9, having a filing date of Feb. 16, 2022, the entire contents both of which are hereby incorporated by reference.

### FIELD OF TECHNOLOGY

The following relates to a method for evaluating measurement data of an energy system.

### BACKGROUND

An energy system comprises components between which different energy types are transported. This can involve e.g., electrical, thermal, fossil energy, or energy which is transported by other material flows. If measurement devices were available for all energy flows between all components of the energy system, a complete energy data set would be available. This is advantageous for the operation of the energy system, in particular for the efficient and therefore also environment-friendly utilization of resources.

However, a dedicated meter is not normally installed for every energy flow in an energy system. There can be a wide variety of reasons for this, e.g., installation and maintenance costs, and also shortage of space can play a part. This means that measurement values are available for only a portion of the energy flows and therefore an incomplete energy data set is available. It would be desirable to obtain measurement data for those energy flows for which no measuring devices are available.

Document US 2018/012157 A1 describes a method for estimating the consumption of a device such as e.g., a washing machine, a television or a computer. A model stored in a computer is used here, the model containing dependencies between consumptions of various of these devices of a set of devices.

### SUMMARY

An Aspect Relates to a Method for Evaluating Measurement Values of an Energy System.

A corresponding device or a system for data processing, a computer program product (non-transitory computer readable storage medium having instructions, which when executed by a processor, perform actions), a corresponding computer-readable data carrier, and a corresponding data carrier signal further form the subject-matter of embodiments of the invention.

The method according to embodiments of the invention relates to the evaluation of measurement values of an energy system. Here, the energy system comprises components which are interconnected by energy flows. Measurement values are available for a portion of the energy flows. Values are calculated for at least some energy flows for which no measurement values are available. To do this, different subsystems of the energy system are considered successively, and a value is calculated for one or more energy flows in each subsystem.

The energy flows can transport the same or different energy types. Examples of energy flows are: electric current, a flow of steam, a flow of cold/hot water, or other types of material flows such as e.g., hydrogen, natural gas or other liquids or gases. In the case of material flows, units of a material flow can be used as a unit for the energy flows. The components of the energy system have at least one input and/or one output for one or more energy flows.

The energy flows can be measured by suitable meters, so that measurement values are available for the energy flows provided with meters. The energy system is not fully equipped with meters, or not all meters are in operation, so that measurement values are available for some energy flows only. For some or all energy flows for which no measurement values are available, a method is proposed with which values can be determined.

A conceptual subdivision of the energy system into subsystems is performed for this purpose. A subsystem comprises one or more components here, including the energy flows connecting them and, optionally, energy flows leaving and/or entering the subsystem. A value for one or more energy flows for which no measurement values are available is calculated for a subsystem of this type using the measurement values associated with this subsystem. This is performed multiple times in succession, wherein a different subsystem is considered in each case. These subsystems can have overlaps here. If one or more values have already been calculated for energy flows, these values can be used as a basis for calculating values in a different subsystem.

The topology of the energy system is stored as a directed graph before the calculation of values for at least some energy flows for which no measurement values are available. This topology comprises at least the components and the energy flows interconnecting them, and also, where appropriate, further energy flows which enter or leave the energy system. The measurement values and the calculated values of energy flows can also be stored for this topology. This can be updated as the calculation of values for energy flows progresses, so that a partially or fully completed picture of the energy system is gradually obtained.

In one development of embodiments of the invention, an equation system is set up in each case for the subsystems with variables in the form of the values to be calculated for energy flows of the subsystem for which no measurement values are available. The measurement values can be incorporated into the equation systems as known variables. An equation system of this type can comprise at least one model equation of a component of the respective subsystem, with at least one parameter describing the efficiency of the component. As with the measurement values, parameters of this type are known variables in the equation system. Apart from the model equations, an equation system further comprises energy and/or mass balance equations.

In an embodiment of the invention, subsystems are determined for which solvable equation systems can be set up. The equation system can be solvable, underdetermined or overdetermined, depending on the energy flows for which measurement values are available. In embodiments of the method, a targeted search is carried out for subsystems for which the number of values to be determined is equal to the number of equations and therefore the equation system is solvable.

At least one incorrect measurement value is identified for a subsystem with an overdetermined equation system. The realization that the at least one incorrect measurement value is contained in a plurality of overdetermined equation systems can be exploited here. The appearance of this measurement value in a plurality of unsolvable equation systems can therefore be regarded as an indication that something is wrong with this measurement value. If a measurement value of this type has been identified, an error message relating to this measurement value can be output. The respective measurement value can further be regarded as unknown in an equation system, possibly resulting in a solvable equation system.

It is advantageous to incorporate a notional measurement value into the equation system for a subsystem with an underdetermined equation system for at least one energy flow for which no measurement value is available. The presence of a measurement value is thereby simulated, possibly resulting in a solvable equation system.

In embodiments, the method according to the invention and/or one or more functions, features and/or steps of the method according to embodiments of the invention and/or one of its embodiments can be executed in a computer-aided manner. One or more interacting computer programs are used for this purpose. If a plurality of programs is used, they can be stored together on one computer and can be executed by the computer or on different computers at different locations. As this is functionally equivalent, the singular forms “the computer program” and “the computer” are used here.

### BRIEF DESCRIPTION

Some of the Embodiments Will be Described in Detail, with Reference to the Following Figures, Wherein Like Designations Denote Like Members, Wherein:

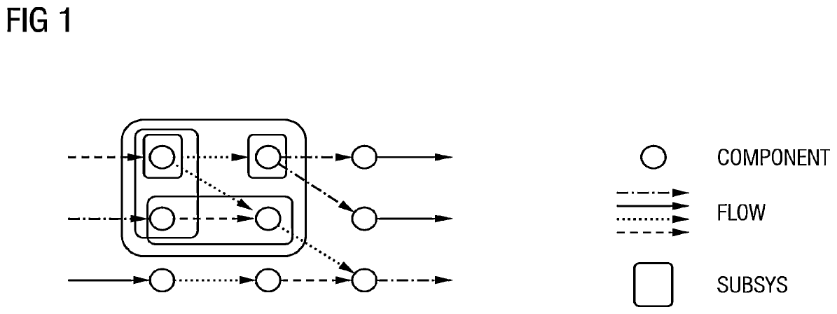

FIG. 1 shows an energy system; and

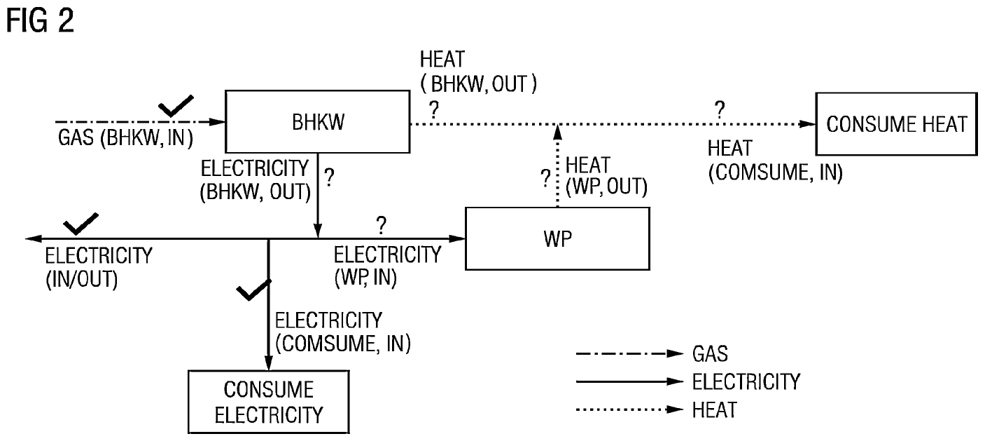

FIG. 2 shows a part of an energy system.

### DETAILED DESCRIPTION

An energy system which is shown schematically in FIG. 1 is considered below. This can be the energy system of a specific location, e.g., a residential complex or a campus, or a larger, multi-site system.

The energy system consists of a plurality of components COMPONENT. These are technical devices or plants which have an input for one energy type and an output for the same or a different energy type, i.e. in the latter case they convert different energy types into one another. Different types of energies here can be electrical energy, fossil energy, heat energy: they are transported by electric current, steam flows or material flows, wherein the material flows can transport e.g., hydrogen or natural gas. Examples of components COMPONENT are cogeneration-based power stations, electrical and/or other energy stores such as aggregates for compressed air, heat pumps, compressors, electric vehicle charging stations, etc.

In FIG. 1, the components COMPONENT are connected by different energy flows FLOW. This connection between the components COMPONENT corresponds to the internal structure or topology of the energy system. This means that the topology of the energy system indicates which component COMPONENT is connected to which or to which other component(s) COMPONENT via which type of energy flow FLOW.

The arrows entering the energy system from the left in the figure indicate that the energy system is connected e.g., to an electricity grid or gas network from which it is supplied with energy. Furthermore, a connection to a different energy system can also be provided. The arrows leaving the energy system to the right in the figure indicate that different consumers can be connected to the energy system. Furthermore, a connection to a different energy system can be provided here also.

A measuring device could ideally be provided for each energy flow FLOW so that values are available for each energy flow FLOW due to the measurement data. This is not normally the case in real systems. On one hand, the procurement, installation and maintenance of the meters are expensive and, on the other hand, the handling of the measurement data, i.e. the transmission and storage of these values, is laborious. It is therefore assumed that the topology is known, but no complete energy data set is available for the energy system. The energy data set is understood here to mean the energy flows FLOW connecting the different components COMPONENT of the energy system.

The aim of the procedure described below is to fully or partially supplement or complete the incomplete energy data arithmetically. Virtual measurement data are therefore intended to be generated on the basis of the known topology and the incomplete energy data set. This is done by a systematic approach which enables gaps in the energy data set to be filled. The virtual measurement data are calculated here automatically by a computer program.

For this purpose, the topology of the energy system is first stored as a directed graph. These values are further assigned to the connections between the components COMPONENT of the energy system for which measurement data for the respective energy flow FLOW are available. This procedure for storing the topology of the energy system in combination with the energy data set should be as granular as possible. In other words, the smallest possible components COMPONENT and the associated energy flows FLOW should be used.

However, in order to reduce complexity, is also possible to combine a plurality of individual components into one large component COMPONENT. In this case, the energy flows taking place within the larger component COMPONENT do not have to be considered and stored, but instead only the energy flows FLOW which enter and leave the larger component.

COMPONENT. One example of a larger component COMPONENT of this type would be a chemical plant which comprises a plurality of chemical reactors as smaller components.

A simple example will be considered as an introduction to the procedure; measurement values are available for the energy flow FLOW for a group of three components COMPONENT, and also for the energy consumption of two of these components COMPONENT. The energy consumption of the third component COMPONENT can be calculated directly therefrom. However, if the measurement value related to an energy flow FLOW for a group of four components COMPONENT, the energy consumption of the third and fourth component COMPONENT would not be calculable. A further measurement value would have to be provided in order to be able to set up an equation system which is neither underdetermined nor overdetermined.

A central aspect is correspondingly to find subsystems within the total energy system within which virtual measurement data can be calculated, whereby an equation system having precisely as many equations as there are virtual measurement data to be determined can be set up on the basis of the known topology. Some subsystems SUBSYS of this type are shown by way of example in the energy system in FIG. 1.

A specific example is explained below with reference to FIG. 2. This does not correspond to a part of FIG. 1, which is used for the more abstract understanding of embodiments of the invention. The subsystem SUBSYS illustrated in FIG. 2 comprises a cogeneration plant BHKW, a heat pump WP, a heat consumer CONSUME HEAT and an electricity consumer CONSUME ELECTRICITY. The different energy flows FLOW are identified by different types of line: the energy flow FLOW of gas is identified by an arrow with a chain line, the energy flow FLOW of electric current is identified by an arrow with a continuous line, and the energy flow FLOW of heat is identified by an arrow with a dotted line.

The topology of the subsystem SUBSYS illustrated in FIG. 2 is as follows: the gas energy flow GAS (BHKW, IN) enters the cogeneration plant BHKW. It comes from a component of the energy system which is not part of the subsystem SUBSYS shown in FIG. 2. Measurement data for this energy flow GAS (BHKW, IN) are available—identified by a tick on the associated arrow—and originate from a gas meter (not shown in the figure).

The heat energy flow HEAT (BHKW, OUT) leaves the cogeneration plant BHKW. There is no meter for the heat energy flow HEAT (BHKW, OUT), identified by a question mark on the associated arrow.

The electricity energy flow ELECTRICITY (BHKW, OUT) further leaves the cogeneration plant BHKW. There is no meter for the electricity energy flow ELECTRICITY (BHKW, OUT), identified by a question mark on the associated arrow.

The electricity energy flow ELECTRICITY (WP, IN) enters the heat pump WP. There is no meter for the electricity energy flow ELECTRICITY (WP, IN), identified by a question mark on the associated arrow.

The heat energy flow HEAT (WP, OUT) leaves the heat pump WP. There is no meter for the heat energy flow HEAT (WP, OUT), identified by a question mark on the associated arrow.

The heat energy flow HEAT (CONSUME, IN) enters the heat consumer CONSUME HEAT. There is no meter for the heat energy flow HEAT (CONSUME, IN), identified by a question mark on the associated arrow.

The electricity energy flow ELECTRICITY (CONSUME, IN) enters the electricity consumer CONSUME ELECTRICITY. Measurement data for this energy flow ELECTRICITY (CONSUME, IN) are available—identified by a cross on the associated arrow—and originate from an electricity meter (not shown in the figure).

The electricity energy flow ELECTRICITY (IN/OUT) which is connected to the cogeneration plant BHKW, the heat pump WP and the electricity consumer CONSUME ELECTRICITY is further located on the left side. Here, the electricity energy flow ELECTRICITY (IN/OUT) can both enter and leave the subsystem SUBSYS shown in FIG. 2.

Measurement Data for this Energy Flow ELECTRICITY (IN/OUT) are Available—Identified by a Cross on the Associated Arrow—and Originate from an Electricity Meter (not Shown in the Figure).

The topology of the subsystem SUBSYS can be described by equations. These equations are, on one hand, energy balance equations, and, on the other hand, model equations of components COMPONENT.

The energy balance equations are based on the law of conservation of energy. According to this law, the incoming and outgoing energy flows FLOW must be equally great in total for any given subsystem SUBSYS. The following applies to the subsystem SUBSYS considered in FIG. 2:

```
  (1) HEAT (BHKW, OUT) + HEAT (WP, OUT) = HEAT (CONSUME,
  IN)
  (2) ELECTRICITY (IN/OUT) = ELECTRICITY (BHKW, OUT) −
ELECTRICITY (WP, IN) − ELECTRICITY (CONSUME, IN)
```

The Model Equations Describe the Efficiency of the Mode of Operation of Components Providing Specific Energy Forms:

```
  (3) ELECTRICITY (BHKW, OUT) = GAS (BHKW, IN) * efficiency
(BHKW, ELECTRICITY)
  (4) HEAT (BHKW, OUT) = GAS (BHKW, IN) * efficiency (BHKW,
  HEAT)
  (5) HEAT (WP, OUT) = ELECTRICITY (WP, IN) * COP (WP)
```

Parameters describing efficiency are used in the model equations. Here, the efficiency parameter (BHKW, ELECTRICITY) describes the efficiency of the provision of electrical energy by the cogeneration plant BHKW, which could, for example, be 33%. The efficiency parameter (BHKW, HEAT) relates accordingly to the efficiency of the provision of thermal energy by the cogeneration plant BHKW, which could, for example, be 55%. The parameter COP (WP) further stands for the coefficient of performance of the heat pump, which could, for example, be 3.5. The latter depends heavily on the process that is used by the heat pump WP, in particular on whether the heat pump draws heat from groundwater or from ambient air.

The two energy balance equations and the three model equations thus provide an equation system consisting of five equations, with the five unknown energy data HEAT (BHKW, OUT), HEAT (WP, OUT), HEAT (CONSUME, IN), ELECTRICITY (BHKW, OUT), ELECTRICITY (WP, IN). By solving the equation system, virtual measurement data can therefore be calculated for these five unknown energy data. A complete set of measurement data for the subsystem SUBSYS shown in FIG. 2 is therefore available.

The units which are used for the values of the energy flows FLOW are kW or MW. In relation to the real measurement values, this involves energy packages that are transmitted within a defined time period. For this purpose, a suitable time basis must be used to read the meters, so that the energy quantities that are considered are those transmitted in a suitably selected time period, e.g., in one minute or a few minutes. Outputs are not therefore considered, since they often do not precisely match one another: inertias or capacitances are often present in lines, e.g., in various pipelines. The “accumulation” of the energy quantity over the defined time period results in a temporal averaging so that the effect of the inertia is barely significant.

A different approach should be adopted for components which store so much energy that this does not average out within a few minutes: these components can be modelled explicitly as energy stores. A battery or a hot water storage tank are examples. The described method is also well suited to storage devices, since it is a major problem in practice to determine the energy content of a storage device. In addition, along with the energy flows already explained, the storage level is also introduced into the equation system as a further variable.

As already explained above, a fundamental aspect is to find subsystems in the entire energy system in which all virtual measurement data can be calculated. This is enabled by storing the energy balance equations and the model equations for the entire system together with the topology. The computer program therefore forms and considers different subsystems until one subsystem is found in which the calculation of all virtual measurement data is possible. FIG. 1 shows by way of example five different subsystems SUBSYS. One subsystem SUBSYS essentially consists of one or more components COMPONENT of the energy system which are interconnected with energy flows FLOW. Although the subsystems shown in FIG. 1 are rectangles, they can also have shapes that differ therefrom.

Following the calculation of the virtual measurement data for a subsystem, these virtual measurement data—and also the real measurement data—are stored together with the topology. This is followed by a search for the next subsystem SUBSYS in which all virtual measurement data are calculable. A prerequisite here is that the previously calculated virtual measurement data are known. In this way, the energy data set of the energy system can gradually be completed as far as possible.

In the simplest situation, the complete energy data set can be determined in the manner described above. This implies that equation systems are gradually found in which the number of unknowns, i.e. the virtual measurement data to be calculated, matches the number of equations. In reality, however, the situation often occurs where, after a number of calculations, only overdetermined or undetermined equation systems can be set up. In other words, the energy data set is not yet complete, as all virtual measurement data have not yet been determined, but a suitable subsystem SUBSYS which enables a direct calculation of virtual measurement data can no longer be found.

In this situation, it can suffice to terminate the algorithm. This is the case if it is not necessary to have the complete energy dataset available. It may be that a portion of measurement data of the energy data set supplies sufficient information. This portion has been maximized by the method described, i.e. the quantity of unknown virtual measurement data has been minimized.

The fact that the situation portrayed will normally occur in which only overdetermined or undetermined equation systems can be set up is also the reason why, instead of the described iterative procedure, the complete energy data set is not calculable by solving a single equation system based on the complete energy system. This equation system is usually not solvable due to underdetermination or overdetermination. As already explained, the division of the problem into subproblems supplies the greatest possible number of calculable virtual measurement data.

### Concerning the Case of the Overdetermined Equation Systems:

There is no solution here, from a mathematical point of view, for the respective data missing from the energy data set. The reason for this is that different meters supply values that are inconsistent with one another. This can have different causes. On one hand, it may be that a meter is defective and therefore supplies incorrect measurement results, or fails completely and outputs the measurement value zero. On the other hand, the cause may be a lack of measurement accuracy or time delays in the measurement values.

A plurality of approaches is possible in this overdetermined equation system scenario. It is particularly appropriate to identify a meter of which the values are contained in a plurality of equation systems that are unsolvable due to overdetermination. This can also indicate that this meter is malfunctioning. Its measurement values can therefore be set to unknown so that at least some of the equation systems are solvable. The latter step can be preceded by a plausibility check to determine whether the measurement data of the meter concerned represent useful values: its measurement results will be ignored, and the respective energy flow will be regarded as unknown only if this is not the case. The measurement data of the defective meter will be replaced by the virtual measurement data calculated for this meter after the equation system has been solved. In addition, or as an alternative to this modification of measurement data, it is also possible to search in an overdetermined equation system for those virtual measurement data which result in the smallest error within the equation system, i.e. which represent the best possible solution. Suitable optimization algorithms can be used for this purpose.

A plurality of different virtual measurement data can further be determined for the missing values in the case of the overdetermined equation system. The resulting value range is a good estimate of the measurement accuracy for determining the respective specific value.

### Concerning the Underdetermined Equation Systems:

In this scenario, the simplest option is to use notional measurement data for one or more meters. These data can correspond e.g., to typical measurement data of similar types of other meters in a similar position within the energy system. An averaging of measurement data from other meters is also useful. If the meter concerned previously supplied measurement data and has since failed, its outdated measurement data can be used.

In embodiments, the methods described can be executed automatically by a computer. For this purpose, the program requires as inputs the topology of the energy system, including the equations and relationships which describe the internal structure of the network, and the measurement data. The computer program determines as many virtual measurement data as possible on this basis. A further output variable can be the indication of one or more meters identified as defective, e.g., in the form of an error message.

In some scenarios, it may not be of interest to have the complete energy data set available. Instead, it could be that only one or more virtual measurement data are required. This can be specified in the computer program so that the computer program attempts to calculate these variables only.

The determination of virtual measurement data has been described on the basis of energy balance equations and model equations. Mass balance equations can also be used instead of energy balance equations. This can be advantageous for hydraulic systems, i.e. water networks, district heating networks, etc. Similar to the energy balance equations, the mass balance equations can be set up here on the basis of the mass conservation in these systems.

In addition, or as an alternative to determining the virtual measurement data, it is possible to calculate or verify all or some of the parameters in the equations. To do this, these parameters are regarded in the respective equation systems as variables which are unknown and are therefore to be calculated.

In embodiments, the method described has the following advantages: energy flows FLOW can also be determined for parts of the energy system which are not equipped with meters. This enables cost savings, since fewer meters are required, or meters do not have to be specially installed.

The virtual data can further contribute to the more efficient operation of the energy system on the basis of the energy data set at least partially completed therewith.

If it turns out that specific measurement data or a group of measurement data are not mathematically determinable, one or more meters can be installed specifically at this position within the energy system.

Following the identification of defective meters on the basis of inconsistent measurement data, these meters can be repaired, and the energy system can be operated more effectively with correct measurement data of the repaired meters.

Since defective meters are identified, it can be assumed with greater certainty that the other meters are operating reliably. This can be taken into account in the planning of maintenance cycles. A systematic database is already available for the entire energy system due to the input of the topology with the relationships between the components contained in equations and even more so due to the enrichment of the energy data set with the virtual measurement data. This can be used for a wide variety of purposes; consistent, good data form the basis in many areas: e.g., monitoring, analytics, operational optimization. The data are suitable, for example, for checking whether the components are also actually interconnected as planned. Short circuits in electrical systems and leaks in thermal, hydraulic or pneumatic systems can therefore also be detected.

Although the present invention has been disclosed in the form of embodiments and variations thereon, it will be understood that numerous additional modifications and variations could be made thereto without departing from the scope of the invention.

For the sake of clarity, it is to be understood that the use of “a” or “an” throughout this application does not exclude a plurality, and “comprising” does not exclude other steps or elements.

1-13. (canceled)

14. A method for evaluating measurement data of an energy system, wherein the energy system comprises components which are interconnected by energy flows, wherein
measurement values are available for a portion of the energy flows,
values are calculated for at least some energy flows for which no measurement values are available, whereby
different subsystems of the energy system are considered successively, and in each subsystem a value is calculated for one or more energy flows for which no measurement values are available, wherein
virtual measurement data are calculated in the subsystems by setting up an equation system based on a topology.

15. The method as claimed in claim 14, wherein
the topology of the energy system is stored as a directed graph before the calculation.

16. The method as claimed in claim 15, wherein
measurement values and the calculated values for energy flows are stored for the topology.

17. The method as claimed in claim 14, wherein
the equation system is set up in each case for the subsystems with variables in the form of values to be calculated for energy flows of the subsystem for which no measurement values are available.

18. The method as claimed in claim 17, wherein
the equation system comprises at least one model equation of a component of the respective subsystem, with at least one parameter describing an efficiency of the component.

19. The method as claimed in claim 17, wherein
subsystems are determined for which solvable equation systems are set up.

20. The method as claimed in claim 17, wherein
at least one incorrect measurement value is identified for a subsystem with an overdetermined equation system.

21. The method as claimed in claim 20, wherein
the at least one incorrect measurement value is identified in that the at least one incorrect measurement value is identified as a component of a plurality of overdetermined equation systems.

22. The method as claimed in claim 17, wherein
a notional measurement value is incorporated into the equation system for a subsystem with an underdetermined equation system for at least one energy flow for which no measurement value is available.

23. A device or system for data processing, comprising means to carry out the method as claimed in claim 14.

24. A computer program product, comprising a computer readable hardware storage device having computer readable program code stored therein, said program code executable by a processor of a computer system to implement a method, as claimed in claim 14.

25. A computer-readable data carrier on which the computer program as claimed in claim 24, is stored.

26. A data carrier signal which contains the computer program as claimed in claim 24.
